(19) United States
(12) Patent Application Publication
(10) Pub. No.: US 2026/0305249 A1
(43) Pub. Date: Oct. 1, 2026

(54) POROUS PLUG ASSEMBLY, ELECTROSTATIC CHUCK, AND PLASMA ETCHING APPARATUS

(71) Applicant: Advanced Micro-Fabrication Equipment Inc. China, Shanghai (CN)

(72) Inventors: Erfei GUO, Shanghai (CN); Taotao ZUO, Shanghai (CN)

(21) Appl. No.: 19/142,705

(22) PCT Filed: Nov. 29, 2023
(86) PCT No.: PCT/CN2023/135071

§ 371 Date: Nov. 11, 2025

(30) Foreign Application Priority Data
Dec. 29, 2022 (CN) 202211717146.9

(51) Int. Cl. H10P 72/72; H01J 37/32; H10P 72/00

(52) U.S. Cl. CPC H10P 72/722; H01J 37/32724; H10P 72/0421; H01J 2237/002; H01J 2237/2007; H01J 2237/334

(57) ABSTRACT

Disclosed are a porous plug assembly, an electrostatic chuck, and a plasma etching apparatus. The porous plug assembly includes a porous plug body with a porous structure, wherein a gas enters from a bottom surface of the porous plug body, passes through the porous plug body, and flows out from a top surface of the porous plug body; and an insulating dense layer, including a lateral portion and a transverse portion, wherein the lateral portion is formed on a side wall of the porous plug body, and the transverse portion at least extends toward one of a direction away from the porous plug body and a direction close to the porous plug body from a top end of the lateral portion. The transverse portion reduces the risk that a bonding layer is eroded by a plasma. The porous plug assembly further reduces the discharge space and the risk of generating arching. The porous plug assembly further effectively solves the problem that the bonding layer blocks the porous plug body.

### CROSS REFERENCE TO RELATED APPLICATION

This application is a national phase application of International Application No. PCT/CN2023/135071, filed on Nov. 29, 2023, which claims priority to Chinese Application No. 202211717146.9, filed on Dec. 29, 2022. All of the above-referenced applications are incorporated herein by reference in their entirety.

### TECHNICAL FIELD

The present disclosure relates to the field of plasma equipment, and in particular, to a porous plug assembly, an electrostatic chuck, and a plasma etching apparatus.

### BACKGROUND

An electrostatic chuck is a key component for a plasma etching apparatus. A dielectric plate is adhered to a base of the electrostatic chuck as a supporting platform of a wafer. Moreover, an air hole is formed in the electrostatic chuck. A cooling gas flows to the back surface of the wafer through the air hole to absorb the heat of the wafer, so that the temperature of the wafer is decreased. With the development of storage technology, the plasma etching apparatus uses increasingly high radio frequency power. The voltage borne by the electrostatic chuck is increasingly high. When the wafer is processed with the plasma, the cooling gas in the air hole is susceptible to breakdown to generate arching to damage the wafer and the electrostatic chuck.

In the prior art, a porous plug is placed in the air hole to improve the breakdown withstand voltage at the air hole. However, at present, due to various factors such as increasingly demanding process requirements, inaccuracy during production and processing and various influences (for example, adverse influences caused by thermal expansion and contraction of the electrostatic chuck) generated in the using process of the electrostatic chuck, a higher requirement on the breakdown withstand degree of the porous plug is proposed.

### SUMMARY

An objective of the present disclosure is to provide a breakdown withstand porous plug assembly, an electrostatic chuck, and a plasma etching apparatus.

In order to achieve the above objective, the present disclosure provides a porous plug assembly, including:
a porous plug body with a porous structure, the porous plug body including a top surface, a bottom surface, and a side wall, where a gas enters from the bottom surface, passes through the porous plug body, and flows out from the top surface; and
an insulating dense layer, including a lateral portion and a transverse portion, where the lateral portion is disposed on the side wall of the porous plug body and is provided with a top end and a bottom end, the bottom end is coplanar with the bottom surface, and the top end is not lower than the top surface; and
the transverse portion at least extends toward one direction away from the porous plug body and a direction close to the porous plug body from the top end of the lateral portion, and an upper surface of the transverse portion is coplanar with the top end.

In an embodiment, the transverse portion at least extends toward the direction close to the porous plug body, and a lower surface of the transverse portion is not higher than the top surface.

In an embodiment, the lower surface of the transverse portion is coplanar with the top surface and covers a part of the top surface.

In an embodiment, the lower surface of the transverse portion is lower than the top surface, and an area of the top surface is smaller than an area of the bottom surface.

In an embodiment, the transverse portion further extends toward the direction away from the porous plug body.

In an embodiment, an elastic member is disposed at the bottom end of the lateral portion.

In an embodiment, a porosity of the porous plug body is 30% to 60%.

In an embodiment, the porous plug body is a porous ceramic, and the dense layer is a ceramic.

The present disclosure further provides an electrostatic chuck, including:

a base, where a first through hole is formed in the base, and the porous plug assembly described above is disposed in the first through hole; and
a dielectric plate, where an electrode for generating an electrostatic attraction is disposed in the dielectric plate, an upper surface of the dielectric plate is used to fix a wafer, and a lower surface of the dielectric plate is connected to the base through a bonding layer; and the transverse portion is located between the lower surface of the dielectric plate and the base; and
a second through hole axially penetrating through the dielectric plate is formed in the dielectric plate, and the second through is in communication with the first through hole.

In an embodiment, the transverse portion at least extends toward a direction away from the porous plug body, and the bonding layer is disposed between the lower surface of the transverse portion and the base.

In an embodiment, an upper surface of the base is step-shaped and is provided with a lower first upper surface and a higher second upper surface, and the bonding layer is disposed between the lower surface of the transverse portion and the first upper surface.

In an embodiment, an insulating layer is disposed between the bonding layer and the base.

In an embodiment, the insulating layer is aluminum oxide.

In an embodiment, the bonding layer is disposed between the lateral portion and the base.

The present disclosure further provides a plasma etching apparatus, including a process chamber, the electrostatic chuck described above, an upper electrode, a cooling apparatus, and a radio frequency power source, where
the electrostatic chuck is placed in the process chamber to support a wafer and serves as a lower electrode of the process chamber; the cooling apparatus is in communication with the electrostatic chuck for conveying a cooling gas to the wafer; and the upper electrode and the electrostatic chuck are disposed opposite to each other, and the radio frequency power source is applied to the upper electrode or the electrostatic chuck to generate a radio frequency electric field between the upper electrode and the electrostatic chuck to dissociate a reaction gas into a plasma, so as to etch the wafer.

Compared with the prior art, the present disclosure at least includes the following beneficial effects:
(1) The porous plug assembly provided by the present disclosure includes the porous plug body of the porous structure and the insulating dense layer, where the dense layer includes the lateral portion and the transverse portion, and the transverse portion can protect the bonding layer effectively, so that the risk that the bonding layer is corroded by the plasma is reduced, and the corrosion resistance of the electrostatic chuck is improved.
(2) The transverse portion of the dense layer provided by the present disclosure can prevent the porous plug body from blocking the hole as the bonding layer enters from the top surface of the porous plug body.
(3) The bonding layer is disposed of between the transverse portion of the dense layer and the base, and the elastic member is disposed of at the bottom end of the lateral portion of the dense layer to compensate for the slit between the dielectric plate and the transverse portion of the dense layer, so as to prevent the generation of arching due to a large slit.
(4) The dense layer provided by the present disclosure further reduces the discharge space and the risk of generating arching. The transverse portion extending outward, the bonding layer, and the aluminum oxide insulating layer are overlapped to greatly improve the breakdown withstand voltage, and even if the bonding layer or the aluminum oxide insulating layer is defective, it also has a good breakdown withstand effect.

### BRIEF DESCRIPTION OF THE DRAWINGS

FIG. 1 is a schematic structural diagram of a plasma etching chamber.

FIG. 2 is a schematic structural diagram of an existing electrostatic chuck.

FIGS. 3-8 are schematic structural diagrams of a porous plug assembly provided by the present disclosure.

FIGS. 9-15 are schematic structural diagrams of an electrostatic chuck provided by the present disclosure.

In the drawings,
100, electrostatic chuck;
110, base;
111, first through hole;
112, channel;
120, bonding layer;
1201, first bonding layer;
1202, second bonding layer;
1203, third bonding layer;
121, end surface;
130, dielectric plate;
131, second through hole;
140, insulating layer;
200, wafer;
300, plasma;
400, upper electrode;
500, cooling apparatus;
600, 700, porous plug assembly;
610, 710, porous plug body;
611, 711, bottom surface;
612, 712, top surface;
6120, gap;
6121, slit;
620, 720, dense layer;
621, lateral portion;
6211, top end;
6212, bottom end;
622, transverse portion;
630, elastic member.

### DETAILED DESCRIPTION OF THE EMBODIMENTS

The technical solutions of the present disclosure will be described clearly and intactly below in conjunction with drawings. Apparently, the described embodiments are merely a part of embodiments, rather than all the embodiments, of the present disclosure. Based on the embodiments of the present disclosure, all other embodiments obtained by those of ordinary skill in the art without creative work are included in the protection scope of the present disclosure.

In the descriptions of the present disclosure, it should be noted that an orientation relationship or a position relationship indicated by the terms “upper”, “lower”, “left”, “right”, “perpendicular”, “horizontal”, “inside”, “outside”, and the like is an orientation relationship or a position relationship based on the drawing and is merely for ease of describing present disclosure and simplifying the description, rather than indicating or implying that a specified apparatus or element necessarily has a specific orientation or is constructed and operated in a specific orientation. Therefore, the terms should not be construed as a limitation on the present disclosure. In addition, the terms “first”, “second”, “third”, and the like are just used for the purpose of description, but cannot be understood as indicating or implying the relative importance thereof.

In the description of the present disclosure, unless otherwise specified, the terms “mount”, “connect”, “connection”, and the like should be understood in a broad sense, for example, it may be a fixed connection or a detachable connection or an integrated connection; it may be a mechanical connection; it may be a direct connection or an indirect connection via an intermediate, or it may be an internal connection of two components. Those of ordinary skill in the art can understand the specific meanings of the above terms in the present disclosure in specific situations.

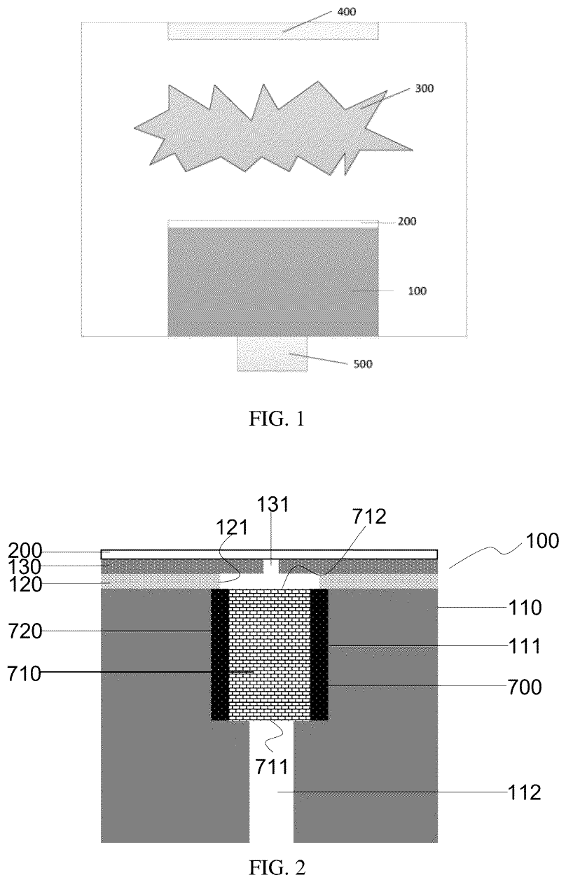

A plasma processing apparatus in a plasma etching chamber is shown in FIG. 1. An electrostatic chuck 100 is a supporting platform for a wafer 200 and is also a lower electrode of a process chamber. An upper electrode 400 of the process chamber and the electrostatic chuck 100 are disposed opposite to each other. A radio frequency power source is applied to the upper electrode 400 or the electrostatic chuck 100 to generate a radio frequency electric field between the upper electrode 400 or the electrostatic chuck 100 to dissociate a reaction gas into a plasma 300, so as to process the wafer 200 fixed on the electrostatic chuck 100. The electrostatic chuck 100 can further regulate the temperature of the wafer 200 placed thereon. An air hole is formed in the electrostatic chuck 100, the electrostatic chuck 100 is connected to a cooling apparatus 500, and a cooling gas in the cooling apparatus 500 flows to a back surface of the wafer 200 through the air hole to absorb the heat of the wafer 200, so that the temperature of the wafer 200 is reduced.

As shown in FIG. 2, the electrostatic chuck 100 includes a base 110 and a dielectric plate 130 disposed on the base 110, and the dielectric plate 130 is connected to the base 110 through a bonding layer 120. An electrode for generating an electrostatic attraction is disposed of in the dielectric plate 130. In order to regulate the temperature of the wafer 200, a first through hole 111 is formed in the base 110, a second through hole 131 axially penetrating through the dielectric plate 130 is formed in the dielectric plate 130, and the second through hole 131 is in communication with the second through hole 111. The first through hole 111 is connected to the cooling apparatus (not shown in the figure) through channel 112, and the cooling gas flows out from the cooling apparatus and passes through channel 112, the first through hole 111, and the second through hole 131 to contact with the back surface of the wafer 200 fixed on the dielectric plate 130, so as to regulate the temperature of the wafer 200.

Under an action of a high-power radio frequency electric field, the cooling gas in the through hole 111 is likely to generate arching, resulting in arching damage of the electrostatic chuck 100. Conditions of breakdown of the cooling gas include: (1) a voltage difference is greater than a voltage threshold at which the cooling gas is subjected to breakdown; and (2) a discharge space is large enough, i.e., the discharge space is much larger than an average free path of the cooling gas, to meet the continuity of the arching effect.

In the prior art, a porous plug assembly 700 is disposed of in the first through hole 111, including a porous plug body 710 and a dense layer 720. The porous plug body 710 is of a porous structure, and the cooling gas can enter from the bottom surface 711 of the porous plug body 710, pass through the porous plug body 710, flow out from the top surface 712, and enter the second through hole 131 to contact the wafer 200. After the porous plug assembly 700 is filled, the discharge space of the cooling gas in the first through hole 111 is reduced, so that the probability of breakdown of the cooling gas is reduced. The insulating dense layer 720 is disposed on a side wall of the porous plug body 710, so that the breakdown with stand performance of the porous plug body 710 can be improved.

However, with increasing improvement of wafer processing process precision, the radio frequency power applied to the electrostatic chuck 100 is increased continuously. Under the action of this high-power radio frequency electric field, further improvement of the breakdown with stand performance of the porous plug assembly 700 is required. By adopting the above porous plug assembly 700, the slit between the dielectric plate 130 and the porous plug assembly 700 is too large (usually the thickness of the bonding layer 120), facilitating the generation of arc discharge, particularly the generation of arc discharge at the end surface 121 of the bonding layer 120. In addition, the bonding layer 120 is usually an organic adhesive. Compared with the dense layer 720, the bonding layer 120 is easily susceptible to corrosion of the plasma. The corroded bonding layer 120 cannot cover the base 110, so the risk of generating arching will be increased.

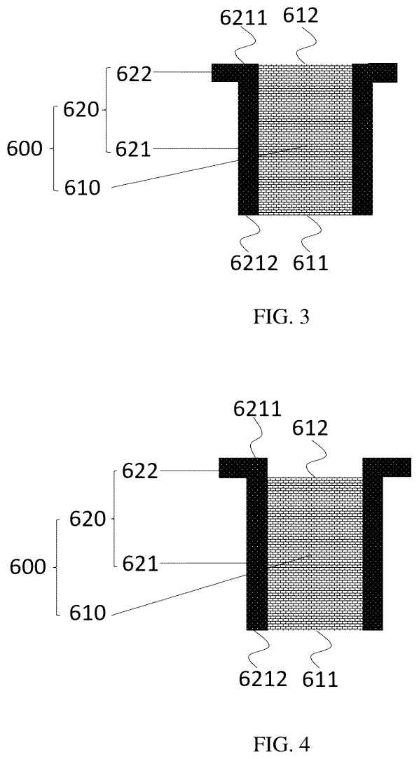

In view of this, the present application provides a porous plug assembly capable of reducing the breakdown risk of the electrostatic chuck. As shown in FIGS. 3-8, the porous plug assembly 600 provided by the present application includes a porous plug body 610 of a porous structure and a dense layer 620. The porous plug body 610 can be in a cylinder shape or any other shape, and the dense layer 620 surrounds the side wall of the porous plug body 610. The porous plug body 610 can be a porous ceramic, such as aluminum oxide or aluminum nitride. The through hole in the porous ceramic can be a linear channel or a curved channel.

The cooling gas enters from the bottom surface 611 of the porous plug body 610, passes through the porous plug body 610, and flows out from the top surface 612 of the porous plug body 610. In this embodiment, a porosity of the porous plug body 610 is 30% to 60%. If the porosity is less, the flow of the cooling gas passing through the porous plug body 610 is too small, and if the porosity is great, the voltage with stand performance of the porous plug body 610 will be too low. Preferably, the porosity of the porous plug body 610 is 50%.

The dense layer 620 includes a lateral portion 621 and a transverse portion 622, where the lateral portion 621 is formed on the side wall of the porous plug body 610, the transverse portion 622 is formed at a top end 6211 of the lateral portion 621, and the transverse portion 622 extends toward one of a direction (i.e., outward)away from the porous plug body 610 and a direction (i.e., inward) close to the porous plug body 610. An upper surface of the transverse portion 622 is basically coplanar with the top end 6211 of the lateral portion 621. The dense layer 620 is at least one of a ceramic, an epoxy resin, and a silicon resin.

In the embodiment shown in FIG. 3, the transverse portion 622 extends outward, and the top surface 612 of the porous plug body is not covered with the dense layer 620. In the embodiment, the upper surface of the transverse portion 622 and the top end 6211 of the lateral portion 621 are basically coplanar with the top surface 612 of the porous plug body 610, and the bottom end 6212 of the lateral portion 621 is basically coplanar with the bottom surface 611 of the porous plug body 610.

In the embodiment shown in FIG. 4, the bottom end 6212 of the lateral portion 621 is basically coplanar with the bottom surface 611 of the porous plug body 610, and the top end 6211 of the lateral portion 621 is higher than the top surface 612 of the porous plug body 610, i.e., the distance between the bottom end 6212 and the top end 6211 of the lateral portion 621 is greater than the axial length of the porous plug body 610.

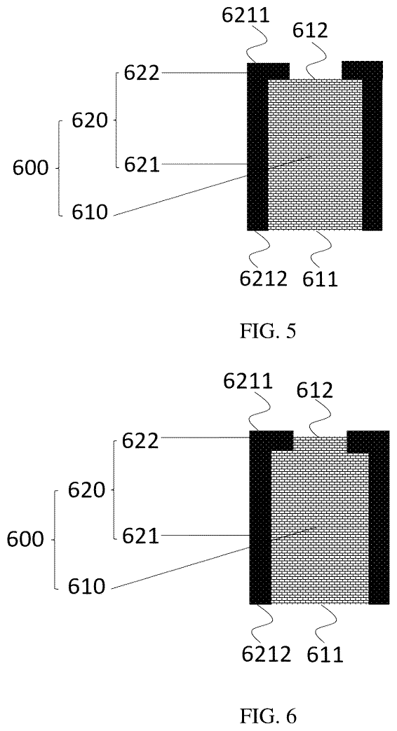

In the embodiment shown in FIG. 5, the transverse portion 622 extends inward, the lower surface of the transverse portion 622 is basically coplanar with the top surface 612, i.e., the transverse portion 622 covers a part of regions of the top surface 612, and the gas flows out from the region of the top surface 612 not covered with the dense layer 620.

In the embodiment shown in FIG. 6, the transverse portion 622 extends inward, the upper surface of the transverse portion 622 is not lower than the top surface 612, the lower surface of the transverse portion 622 is lower than the top surface 612, the area of the top surface 612 is smaller than that of the bottom surface 611, and the porous plug body 610 is substantially in a shape of a Chinese character “ [symbol] ”. In this case, the distance between the bottom end 6212 and the top end 6211 of the lateral portion 621 is not less than the distance from the bottom surface 611 to the top surface 612 of the porous plug body 610.

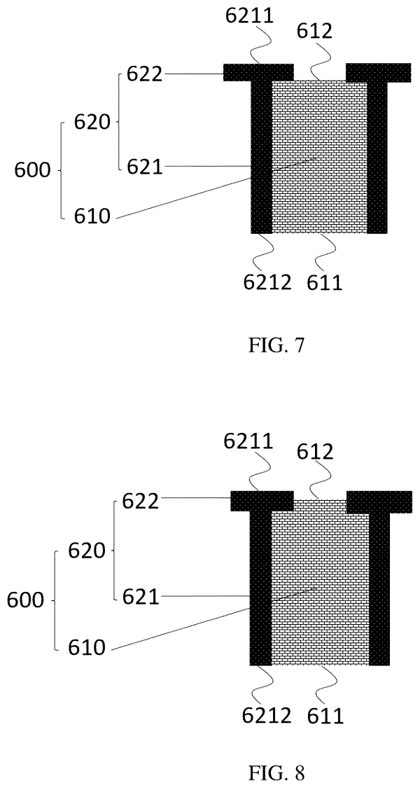

Compared with FIGS. 5 and 6, in the embodiments shown in FIGS. 7 and 8, the transverse portion 622 extends inward and outward at the same time, so that the section of the dense layer 620 is substantially of a T-shaped structure.

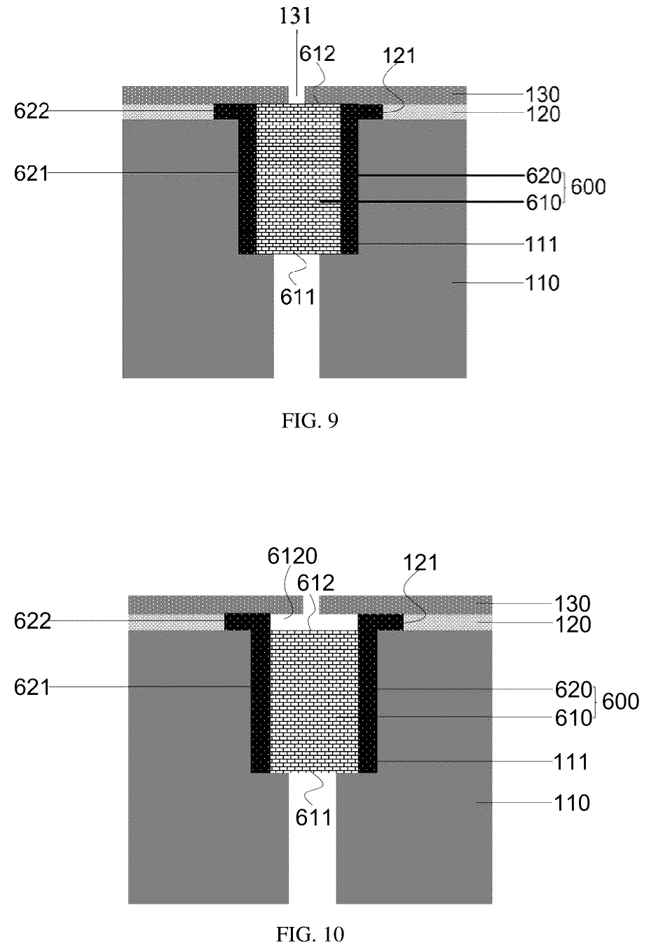

The present disclosure further provides an electrostatic chuck including the porous plug assembly 600 described above. As shown in FIG. 9, a first through hole 111 is formed in the base 110, and the porous plug assembly 600 is disposed of in the first through hole 111. A dielectric plate 130 is placed on the base 110, and the upper surface of the dielectric plate 130 is used for fixing the transverse portion of the wafer. A second through hole 131 axially penetrating through the dielectric plate 130 is formed in the dielectric plate 130, and the second through 131 is in communication with the first through hole 111. A bonding layer 120 is disposed between a lower surface of the dielectric plate 130 and the base 110, and is used for adhering the dielectric plate 130 and the base 110.

In the embodiment, the transverse portion 622 extends outward, so that the bonding layer 120 is surrounded by the base 110, the dense layer 620, and the dielectric plate 130. The end surface 121 of the bonding layer 120 is shielded by the dense layer 620 and is not directly exposed to a plasma environment. The dense layer 620 is good in corrosion resistance and can protect the end surface 121 of the bonding layer 120. Compared with the prior art, the discharge space between the dielectric plate 130 and the porous plug assembly 600 is small, which is harmful to generating arc discharge. The dense layer 620 also has a very high breakdown withstand voltage and can improve the breakdown withstand performance of the surrounding region of the porous plug body 610.

In the embodiment shown in FIG. 10, the upper surface of the transverse portion 622 is higher than the top surface 612 of the porous plug body 610. In the embodiment, there is a gap 6120 between the lower surface of the dielectric plate 130 and the top surface 612. The dielectric plate 130 does not contact with the top surface 612, so the blockage of the dielectric plate 130 on gas outflow can be reduced. The dense layer 620 has a very high breakdown withstand voltage and can improve the breakdown withstand performance of the surrounding region of the porous plug body 610.

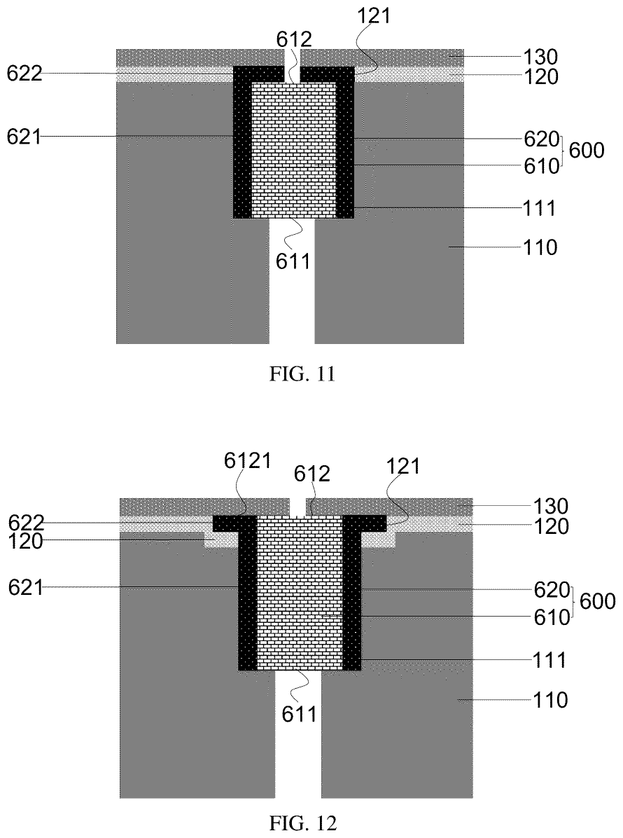

In the embodiment shown in FIG. 11, the transverse portion 622 extends inward. The dielectric plate 130 is placed on the transverse portion 622 of the dense layer 620, the upper surface of the base 110 is not higher than the upper surface of the transverse portion 622, and a bonding layer 120 fills a space between the base 110 and the dielectric plate 130. The bonding layer 120 is surrounded by the base 110, the dense layer 620, and the dielectric plate 130. The end surface 121 of the bonding layer 120 is shielded by the dense layer 620 and is not directly exposed to a plasma environment. The extended transverse portion 622 covers a part of regions of the top surface 612, and the plasma cannot penetrate through the transverse portion 622 of the dense layer 620 along the top surface 612 of the porous plug body 610 to corrode the bonding layer 120.

The bonding layer 120 is usually formed by a moving jelly. When the bonding layer 120 is processed, the jelly easily flows to the porous plug body 610 to lead to hole blockage, which affects the permeability of the porous plug body 610. The transverse portion 622 of the dense layer 620 in the embodiment covers a part of regions of the top surface 612. Through the extended transverse portion 622, the distance between the region (i.e., the region not covered with the transverse portion 622) where the gas flows out on the top surface 612 of the porous plug body 610 and the bonding layer 120 is increased, so that the bonding layer 120 is unlikely to flow to the top surface 612 of the porous plug body 610 to lead to hole blockage. It is worth noting that the transverse portion 622 extending outward can also play a role in preventing the adhesive jelly from blocking the hole. Compared with the prior art, the discharge space between the dielectric plate 130 and the porous plug assembly 600 is small, which is harmful to generating arc discharge. The dense layer 620 also has a very high breakdown withstand voltage and can improve the breakdown withstand performance of the surrounding region of the porous plug body 610.

When the electrostatic chuck is processed, the first through hole is usually formed first in the base, the porous plug assembly fills the first through hole, and then the dielectric plate is adhered to the base through the bonding layer. The dielectric plate is pressed axially to reduce the slit between the dielectric plate and the transverse portion of the dense layer and adhere the dielectric plate to the base. The lower surface of the dielectric plate is adjacent to the upper surface of the transverse portion. If there is a slit between the two surfaces, the gap facilitates the generation of arching. However, there may be tolerances among components in the production process and mis-operations may occur in the processing process. The material of the dielectric plate is brittle. If the porous plug assembly and the base are in hard contact, to press the dielectric plate axially, the dielectric plate may be broken. The slit between the lower surface of the dielectric plate and the upper surface of the transverse portion may be larger.

As shown in FIG. 12, a bonding layer 120 is further disposed between the lower surface of the transverse portion 622 and the base 110. Specifically, the upper surface of the base 110 is step-shaped and is provided with a lower first upper surface and a higher second upper surface, and the bonding layer 120 is disposed between the lower surface of the transverse portion 622 and the first upper surface. The bonding layer 120 is made of a flexible jelly. When the dielectric plate 130 is pressed, the bonding layer 120 between the lower surface of the transverse portion 622 and the base 110 can compensate for the slit 6121 between the upper surface of the transverse portion 622 and the dielectric plate 130. After adhesion, the width of the slit 6121 is not greater than 0.1 mm and even no slit exists, so that the transverse portion 622 completely fits the dielectric plate 130.

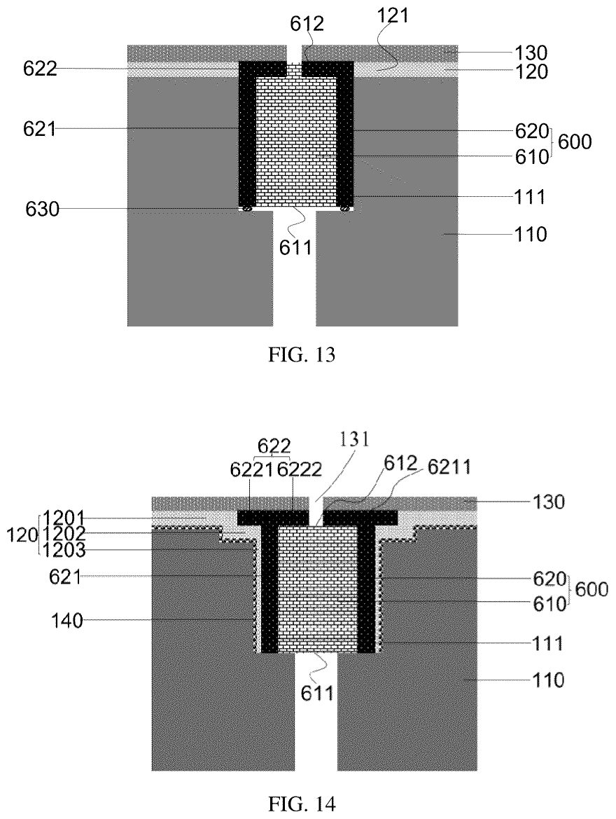

In some other embodiments, particularly embodiments where the transverse portion 622 extends inward, the transverse portion 622 is not overlapped with the base 110, and the slit 6121 cannot be compensated by way of disposing the bonding layer 120 at the transverse portion 622. In order to fully fit the transverse portion 622 with the dielectric plate 130, in the embodiment shown in FIG. 13, an elastic member 630 is disposed at a bottom end of the lateral portion 621 of the dense layer 620. When the dielectric plate 130 is pressed, the overall porous plug assembly 600 moves together with the dielectric plate 130 axially downward, and the elastic member 630 is compressed between the porous plug assembly 600 and the base 110 to compensate for the slit between the transverse portion 622 and the dielectric plate 130.

In some embodiments, an insulating layer is disposed between the bonding layer 120 and the base 110. The insulating layer is aluminum oxide. The insulating layer can further protect the base and isolate direct arc damage between the base 110 and the wafer 200.

In some embodiments, the bonding layer is disposed between the lateral portion 621 and the base 110. The bonding layer 120 between the lower surface of the dielectric plate 130 and the base 110, the bonding layer 120 between the lower surface of the transverse portion 622 and the base 110, and the bonding layer between the lateral portion 621 and the base 110 are communicated with each other.

The present disclosure further provides a plasma etching apparatus, including a process chamber, the electrostatic chuck described above, an upper electrode, a cooling apparatus, and a radio frequency power source, where the electrostatic chuck is placed in the process chamber to support a wafer and serves as a lower electrode of the process chamber; the cooling apparatus is in communication with the electrostatic chuck for conveying a cooling gas to the wafer; and the upper electrode and the electrostatic chuck are disposed opposite to each other, and the radio frequency power source is applied to the upper electrode or the electrostatic chuck to generate a radio frequency electric field between the upper electrode and the electrostatic chuck to dissociate a reaction gas into a plasma, so as to etch the wafer.

The technical solutions of the present disclosure will be introduced below through the following two preferred embodiments.

### Embodiment 1

As shown in FIG. 14, the embodiment provides an electrostatic chuck, including a base 110 and a dielectric plate 130 disposed on the base 100, and the dielectric plate 130 is connected to the base 110 through a bonding layer 120. In order to regulate the temperature of the wafer (not shown in the figure), a first through hole 111 is formed in the base, a second through hole 131 axially penetrating through the dielectric plate 130 is formed in the dielectric plate 130, and the second through hole 131 is in communication with the second through hole 111. The cooling gas passes through the first through hole 111 and the second through hole 131 to contact with the back surface of the wafer fixed on the dielectric plate 130, so as to regulate the temperature of the wafer. In the embodiment, the cooling gas is helium.

A porous plug assembly 600 is disposed in the first through hole 111. The porous plug assembly 600 includes a porous plug body 610 of a porous structure and a dense layer 620. The porosity of the porous plug assembly 610 is 50%, and the gas enters from the bottom surface 611 of the porous plug body 610, passes through the porous plug body 610, and flows out from the top surface 612 of the porous plug body 610. The dense layer 620 is made of a ceramic material with the porosity less than that of the porous plug body 610, and includes a lateral portion 621 and a transverse portion 622, where the transverse portion 622 extends inwards and outwards simultaneously, an upper surface of the transverse portion 622 is basically coplanar with a top end 6211 of the lateral portion 621, and a lower surface of the transverse portion 622 is basically coplanar with a top surface 612.

The transverse portion 622 includes a first member 6221 extending outward and a second member 6222 extending inward. The second member 6222 covers a part of regions of the top surface 612, and the gas flows out from a region of the top surface 612 not covered with the second member 6222.

A bonding layer 120 is a step formed by a first bonding layer 1201 and a second bonding layer 1202 communicating with each other. The first bonding layer 1201 is disposed between a lower surface of the dielectric plate 130 and the base 110, and is used for adhering the dielectric plate 130 to the base 110. The extended first member 6221 occupies a filling space of the first bonding layer 1201, so that the first bonding layer 1201 is away from the region of the porous plug assembly 600 in contact with the plasma, and the plasma hardly corrodes the bonding layer 120. The second bonding layer 1202 is disposed between a lower surface of the first member 6221 and the base 110. The dielectric plate 130 is pressed axially, so that the dielectric plate 130 is connected to the base 110. The first member 6221 extrudes the second bonding layer 1202 as the dielectric plate 130 is pressed, and the flexible second bonding layer 1202 compensates for the slit between the transverse portion 622 and the dielectric plate 130, so that the slit is within 0.1 mm.

The bonding layer 120 can further include a third bonding layer 1203 disposed between the lateral portion 621 and the base 110, and the third bonding layer 1203 is in communication with the second bonding layer 1202, so that the bonding layer 120 is of a communicated overall structure. In other embodiments, there can be no third bonding layer 1203. An insulating layer 140 is further disposed between the bonding layer 120 and the base 110, and the insulating layer 140 is aluminum oxide.

The first member 6221 extending outward, the bonding layer 120, and the aluminum oxide insulating layer are overlapped to greatly improve the breakdown withstand voltage, and even if the bonding layer 120 or the aluminum oxide insulating layer is defective, it also has a good breakdown withstand effect. Compared with the prior art, the discharge space between the dielectric plate 130 and the porous plug assembly 600 is small, which is harmful to generating arc discharge. The transverse portion 622 can protect the bonding layer 120 effectively, so that the risk that the bonding layer 120 is corroded is reduced; and in addition, the transverse portion 622 further can prevent the porous plug body 610 from blocking the hole as the bonding layer 120 enters from the top surface of the porous plug body 610.

### Embodiment 2

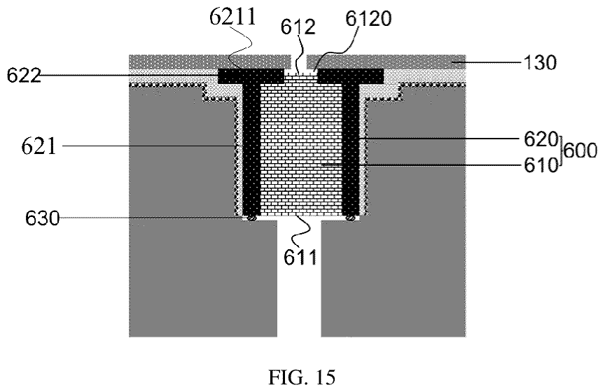

As shown in FIG. 15, the electrostatic chuck provided in the embodiment is substantially the same as that in the Embodiment 1. In the embodiment, the transverse portion 622 extends inward and outward simultaneously, the upper surface of the transverse portion 622 is basically coplanar with the top end 6211 of the lateral portion 621, the lower surface of the transverse portion 622 is lower than the top surface 612, the area of the top surface 612 is smaller than that of the bottom surface 611, and the porous plug body 610 is substantially in a shape of a Chinese character “ [symbol] ”.

The dielectric plate 130 can extend to the top surface 612, so that there is a gap 6120 between the lower surface of the dielectric plate 130 and the top surface 612. The dielectric plate 130 does not contact with the top surface 612, so that the blockage on gas outflow can be reduced.

In the embodiment, an elastic member 630 is disposed at a bottom end of the lateral portion 621, and the elastic member 630 and the second bonding layer 1202 jointly compensate for the slit between the dielectric plate 130 and the transverse portion 622.

To sum up, the present disclosure provides a porous plug assembly, an electrostatic chuck, and a plasma etching apparatus. The porous plug assembly includes the porous plug body of the porous structure and the insulating dense layer, where the lateral portion of the dense layer is formed on the side wall of the porous plug body, the transverse portion is formed at the top end of the lateral portion and extends along a substantially horizontal direction. The extended transverse portion lengthens the distance between the bonding layer of the electrostatic chuck and the plasma, so that the risk that the bonding layer is corroded by the plasma is reduced, and the corrosion resistance of the electrostatic chuck is improved. The porous plug assembly further reduces the discharge space and the risk of generating arching. The porous plug assembly further effectively solves the problem that the bonding layer blocks the porous plug body.

While the present disclosure has been described in detail through the above preferred embodiments, it should be understood that the foregoing description shall not be construed as limiting the present disclosure. Various modifications and alternatives to the present disclosure will be readily apparent to those skilled in the art having read the foregoing description. Accordingly, the protection scope of the present disclosure shall be limited by the appended claims.

1. A porous plug assembly, comprising:
a porous plug body with a porous structure, the porous plug body comprising a top surface, a bottom surface, and a side wall, wherein a gas enters from the bottom surface, passes through the porous plug body, and flows out from the top surface; and
an insulating dense layer, comprising a lateral portion and a transverse portion, wherein the lateral portion is disposed on the side wall of the porous plug body and is provided with a top end and a bottom end, the bottom end is coplanar with the bottom surface, and the top end is not lower than the top surface; and
the transverse portion at least extends toward one of a direction away from the porous plug body and a direction close to the porous plug body from the top end of the lateral portion, and an upper surface of the transverse portion is coplanar with the top end.

2. The porous plug assembly according to claim 1, wherein the transverse portion at least extends toward the direction close to the porous plug body, and a lower surface of the transverse portion is not higher than the top surface.

3. The porous plug assembly according to claim 2, wherein the lower surface of the transverse portion is coplanar with the top surface and covers a part of the top surface.

4. The porous plug assembly according to claim 2, wherein the lower surface of the transverse portion is lower than the top surface, and an area of the top surface is smaller than an area of the bottom surface.

5. The porous plug assembly according to claim 2, wherein the transverse portion further extends toward the direction away from the porous plug body.

6. The porous plug assembly according to claim 1, wherein an elastic member is disposed at the bottom end of the lateral portion.

7. The porous plug assembly according to claim 1, wherein a porosity of the porous plug body is 30% to 60%.

8. The porous plug assembly according to claim 1, wherein the porous plug body is a porous ceramic, and the dense layer is a ceramic.

9. An electrostatic chuck, comprising:
a base, wherein a first through hole is formed in the base, and the porous plug assembly according to claim 1 is disposed in the first through hole; and
a dielectric plate, wherein an electrode for generating an electrostatic attraction is disposed in the dielectric plate, an upper surface of the dielectric plate is used to fix a wafer, and a lower surface of the dielectric plate is connected to the base through a bonding layer; and the transverse portion is located between the lower surface of the dielectric plate and the base; and
a second through hole axially penetrating through the dielectric plate is formed in the dielectric plate, and the second through is in communication with the first through hole.

10. The electrostatic chuck according to claim 9, wherein the transverse portion at least extends toward a direction away from the porous plug body, and the bonding layer is disposed between the lower surface of the transverse portion and the base.

11. The electrostatic chuck according to claim 10, wherein an upper surface of the base is step-shaped and is provided with a lower first upper surface and a higher second upper surface, and the bonding layer is disposed between the lower surface of the transverse portion and the first upper surface.

12. The electrostatic chuck according to claim 9, wherein an insulating layer is disposed between the bonding layer and the base.

13. The electrostatic chuck according to claim 12, wherein the insulating layer is aluminum oxide.

14. The electrostatic chuck according to claim 9, wherein the bonding layer is disposed between the lateral portion and the base.

15. A plasma etching apparatus, comprising a process chamber, the electrostatic chuck according to claim 9, an upper electrode, a cooling apparatus, and a radio frequency power source, wherein
the electrostatic chuck is placed in the process chamber to support a wafer and serves as a lower electrode of the process chamber; the cooling apparatus is in communication with the electrostatic chuck for conveying a cooling gas to the wafer; and the upper electrode and the electrostatic chuck are disposed opposite to each other, and the radio frequency power source is applied to the upper electrode or the electrostatic chuck to generate a radio frequency electric field between the upper electrode and the electrostatic chuck to dissociate a reaction gas into a plasma, so as to etch the wafer.
